(19) United States
(12) Patent Application Publication
(10) Pub. No.: US 2024/0183792 A1
(43) Pub. Date: Jun. 6, 2024

(54) INSPECTION SYSTEM, INSPECTION MANAGEMENT DEVICE, INSPECTING METHOD, AND PROGRAM

(71) Applicant: OMRON Corporation, Kyoto-shi, Kyoto (JP)

(72) Inventor: Takako ONISHI, Kyoto-shi, KYOTO (JP)

(21) Appl. No.: 18/546,470

(22) PCT Filed: Jan. 19, 2022
(86) PCT No.: PCT/JP2022/001722

§ 371 Date: Aug. 15, 2023

(30) Foreign Application Priority Data
Mar. 12, 2021 (JP) 2021-040730

(51) Int. Cl. G01N 21/88; G01N 23/04

(52) U.S. Cl. CPC G01N 21/8851; G01N 23/04; G01N 2021/8867; G01N 2021/8887

(57) ABSTRACT

An inspection system includes a first inspection unit configured to perform a first inspection based on first image data obtained by imaging an inspection target by a first imaging unit, a second inspection unit configured to perform a second inspection based on second image data obtained by imaging the inspection target by a second imaging unit different from the first imaging unit, a first inspection information acquisition unit configured to acquire first inspection information including a result of the first inspection from the first inspection unit, a validity judgment unit configured to judge, based on a predetermined judgment condition, a validity of performing the second inspection on the inspection target by the second inspection unit, and a second inspection execution determination unit configured to determine, based on the judgment by the validity judgment unit, at least a necessity of performing the second inspection.

### TECHNICAL FIELD

The present invention relates to an inspection system, an inspection management apparatus, an inspection method, and a program.

### BACKGROUND ART

In manufacturing processes of various substrates, measurement and inspection using an image obtained by imaging the substrate have been performed, and a technique is known for inspecting, by X-ray computed tomography (CT), a portion which cannot be inspected by appearance. Furthermore, for such an inspection, a technique is known for reinspecting the inspection target judged to be abnormal under imaging conditions corresponding to the type of abnormality (e.g., Patent Literature 1).

Furthermore, a technique is also disclosed in which, in inspecting a substrate using an X-ray inspection apparatus, secondary image data having a higher resolution than that of the primary image data is created on the basis of a plurality of pieces of primary image data acquired during a primary inspection, and a component having an abnormality in the primary image data is reinspected by using the high-resolution secondary image data (e.g., Patent Literature 2). Accordingly, during the secondary inspection, there is no need to acquire further image data for the secondary inspection, and the secondary inspection can be efficiently performed.

### CITATION LIST

### Patent Literature

Patent Literature 1: JP 5246187 B
Patent Literature 2: JP 6484838 B

### SUMMARY OF INVENTION

### Technical Problem

In the techniques described in Patent Documents 1 and 2 above, reinspection with new imaging conditions (including image quality) is performed using a single inspection apparatus for all components judged to be abnormal. According to such methods, reinspection is performed even in a case of a clearly defective product that does not require reinspection or even in a case in which the imaging principles are limited to the extent that there is a problem that cannot be resolved no matter how the imaging conditions (including image quality) are changed under the same imaging principles, resulting in a waste of resources.

The present invention has been made in view of the above circumstances, and an object thereof is to provide a technique that can provide improved inspection efficiency while maintaining inspection accuracy to an inspection system for a component-mounted substrate that includes a plurality of types of inspection apparatuses.

### Solution to Problem

To achieve the object described above, the present invention employs the following configuration. That is, an inspection system includes a first inspection unit configured to perform a first inspection on the basis of first image data obtained by imaging an inspection target by a first imaging unit, a second inspection unit configured to perform a second inspection on the basis of second image data obtained by imaging the inspection target by a second imaging unit different from the first imaging unit, a first inspection information acquisition unit configured to acquire first inspection information including a result of the first inspection from the first inspection unit, a validity judgment unit configured to judge, on the basis of a predetermined judgment condition, a validity of performing the second inspection on the inspection target by the second inspection unit, and a second inspection execution determination unit configured to determine, on the basis of the judgment by the validity judgment unit, at least a necessity of performing the second inspection. Furthermore, in a case in which the second inspection execution determination unit determines to perform the second inspection, the second inspection execution determination unit may also determine content of the second inspection.

The “imaging unit” herein is not limited to a camera that detects a wavelength in a visible light region and may also include an X-ray camera that detects X-rays or a photomultiplier sensor used for laser scanning etc. Furthermore, the “inspection unit” is a unit that performs inspection on the basis of image data obtained by imaging the inspection target, such as a unit that employs automatic optical inspection (AOI) or a unit that employs automatic X-ray inspection (AXI). Furthermore, the “content of the inspection” described above refers to inspection conditions such as an inspection item, a resolution of image data, and an imaging range. The inspection item may include information such as coordinates at which the inspection is performed and a parameter for extracting an inspection target. Furthermore, the “necessity of performing” can be regarded as, for example, a flag indicating whether the inspection target is inspected for a target inspection item by the inspection unit corresponding to the target inspection item. If the flag is ON (inspection necessary), the inspection target is inspected for the target inspection item by the inspection unit corresponding to the target inspection item. If the flag is OFF, the inspection target is not inspected. Furthermore, “determining the content of the second inspection” also includes performing the inspection according to predetermined content in a case in which determination is made to perform the inspection.

According to such a configuration, in a substrate inspection system including a plurality of types of inspection units each having different imaging units, the validity of reinspection in consideration of a difference in the imaging principles of each unit can be judged and the necessity of performing the reinspection (and the inspection content) can be determined on the basis of this judgment. Thus, a reduction in efficiency caused by performing an inspection having low validity (that is, low necessity) can be suppressed.

Furthermore, the second inspection execution determination unit may determine that the second inspection is to be performed in a case in which the result of the first inspection is no abnormality and the validity judgment unit judges that performing the second inspection is valid.

In the prior art, the reinspection is performed only when there is an abnormality in the primary inspection. However, sometimes a defect actually exists but a false negative (so-called missed defect) occurs, such as the case of a non-defective judgement near the threshold of inspection criterion. In this regard, according to the configuration described above, even if “no abnormality (that is, non-defective product)” is judged in the primary inspection, performing the reinspection when performing the secondary inspection is valid makes it possible to suppress such a missed defect and perform inspection with high accuracy. Furthermore, since execution of the secondary inspection is limited to a case in which performing the second inspection is valid, a needless secondary inspection is not performed, and deterioration in inspection efficiency can be prevented.

Furthermore, the inspection system may further include a second inspection information acquisition unit configured to acquire second inspection information including a result of the second inspection from the second inspection unit, and a judgment condition creation unit configured to create an improved judgment condition more appropriate for the judgment condition by using at least the second inspection information. With such a configuration, when the condition for judging the validity of performing the secondary inspection is inappropriate and there is room for improvement on the basis of at least history information of the secondary inspection, the condition can be improved.

Furthermore, the second inspection information may include a second inspection non-defective rate indicating a ratio of a quantity of a plurality of the inspection targets judged to be non-defective to a total quantity of the plurality of inspection targets subjected to the second inspection, and the judgment condition creation unit may perform a process of creating the improved judgment condition in a case in which the second inspection non-defective rate exceeds a predetermined threshold value.

A non-defective product inspection result being obtained even in the secondary inspection means that the possibility of a problem in the result of the primary inspection is low and a needless secondary inspection has been performed. Furthermore, the non-defective rate in the secondary inspection being high presumably means that the judgment condition for judging the validity of performing the secondary inspection is loosely set, which lowers the efficiency of the whole inspection. Therefore, by improving the judgment condition for judging the validity of performing the secondary inspection when the requirements such as described above are satisfied, a decrease in inspection efficiency can be suppressed.

In addition, the inspection system may further include a judgment condition updating unit configured to newly set the improved judgment condition created by the judgment condition creation unit as the predetermined judgment condition. With such a configuration, the judgment condition can be automatically updated. Furthermore, by acquiring the result information of the secondary inspection, improving the judgment condition, and updating the judgement condition to the improved judgment condition in real time, it is possible to construct an inspection system that automatically optimizes the inspection condition. Note that, naturally, the specifications may be employed in which an operator confirms whether to set the improved judgment condition as the new judgment condition at the time of each update rather than the condition being automatically updated.

Furthermore, the validity judgment unit may judge the validity on the basis of the predetermined judgment condition set for at least one of the first image data, a measurement value related to a shape of the inspection target obtained on the basis of the first image data, or information related to design of the inspection target.

Here, the “information related to design of the inspection target” includes, in a case in which the inspection target is a component-mounted substrate, for example, information such as shapes and sizes of components (and lands) and placement relationships between components. Furthermore, as the judgment condition set for the information related to the design of the inspection target, the condition may be set based on likelihood of affecting the primary inspection, such as being a blind spot of another component or being subject to secondary reflection from a solder surface of an adjacent component. Furthermore, as the judgment condition set for the first image data, in some cases, a condition that raises doubts about the reliability of the inspection using the image data, such as “maximum luminance of image data is saturated or minimum luminance is zero” or a “low degree of similarity to typical non-defective product image,” for example, may be set. Furthermore, as the judgment condition set for the measurement value related to the shape of the inspection target obtained on the basis of the first image data, in some cases, a condition in consideration of an error such as low deviation from a threshold value of an inspection criterion may be set.

Furthermore, the validity judgment unit may include a trained model obtained by performing machine learning using a training data set including, of the first image data related to the first inspection performed on the inspection target in the past, the first image data of the inspection target resulting in a false negative and/or a false positive in the first inspection.

Here, “false negative” refers to a so-called missed defect, and “false positive” refers to a so-called over-detection. With such a configuration, it is possible to make an efficient judgement using a trained model trained on the basis of past performance data.

Furthermore, the inspection target may be a component-mounted substrate. Furthermore, the first imaging unit may be a visible light camera, and the second imaging unit may be an X-ray camera. The present invention is suitable for an inspection system under such conditions.

Furthermore, the present invention can also be regarded as an inspection management apparatus that is a management apparatus of an inspection system including a first inspection unit configured to perform a first inspection on the basis of first image data obtained by imaging an inspection target by a first imaging unit, and a second inspection unit configured to perform a second inspection on the basis of second image data obtained by imaging the inspection target by a second imaging unit different from the first imaging unit. The inspection management apparatus includes a first inspection information acquisition unit configured to acquire first inspection information including a result of the first inspection from the first inspection unit, a validity judgment unit configured to judge, on the basis of a predetermined judgment condition, a validity of performing the second inspection on the inspection target by the second inspection unit, and a second inspection execution determination unit configured to determine, on the basis of the judgment by the validity judgment unit, at least a necessity of performing the second inspection.

Furthermore, the present invention can also be regarded as an inspection method including a first inspection step of performing a first inspection on the basis of first image data obtained by imaging an inspection target by a first imaging unit, a first inspection information acquisition step of acquiring first inspection information including a result of the first inspection, a validity judgment step of judging, on the basis of a predetermined judgment condition, a validity of performing a second inspection on the inspection target on the basis of second image data obtained by imaging the inspection target by a second imaging unit different from the first imaging unit, and a second inspection execution determination step of determining, on the basis of the judgment by the validity judgment step, at least a necessity of performing the second inspection and content of the second inspection.

Furthermore, the inspection method may further include a second inspection step of performing the second inspection. The second inspection execution determination step may further include, in a case in which performing the second inspection is determined, also determining content of the second inspection, and the second inspection is performed, in a case in which the content of the second inspection is determined in the second inspection execution determination step, using the content of the second inspection determined.

Furthermore, the inspection method may further include a second inspection information acquisition step of acquiring second inspection information including a result of the second inspection, and an improved judgment condition creation step of creating an improved judgment condition more appropriate for the judgment condition by using at least the second inspection information.

Furthermore, the inspection method may further include a judgment condition updating step of newly setting the judgment condition created in the improved judgment condition creation step as the predetermined judgment condition.

Furthermore, the present invention can also be regarded as a program for causing a computer to execute the method described above, and a computer readable storage medium in which such a program is recorded in a non-transitory manner.

Note that each of the configurations and processes described above can be combined to constitute the present invention as long as there is no technical contradiction.

### Advantageous Effects of Invention

According to the present invention, it is possible to provide a technique that can provide improved inspection efficiency while maintaining inspection accuracy to an inspection system for a component-mounted substrate that includes a plurality of types of inspection apparatuses.

### BRIEF DESCRIPTION OF DRAWINGS

FIG. 1 is a schematic view illustrating a schematic configuration of an inspection system according to an application example.

FIG. 2 is a block diagram illustrating a schematic configuration of the inspection system according to an embodiment.

FIG. 3 is a flowchart illustrating a flow of processing in the inspection system according to the embodiment.

### DESCRIPTION OF EMBODIMENTS

Hereinafter, an implementation example according to the present invention will be described with reference to the drawings. However, dimensions, materials, shapes, relative arrangements, and the like of constituent elements described in the following example are not intended to limit the scope of the present invention unless otherwise specified.

<Application Example>

(Configuration of Application Example)

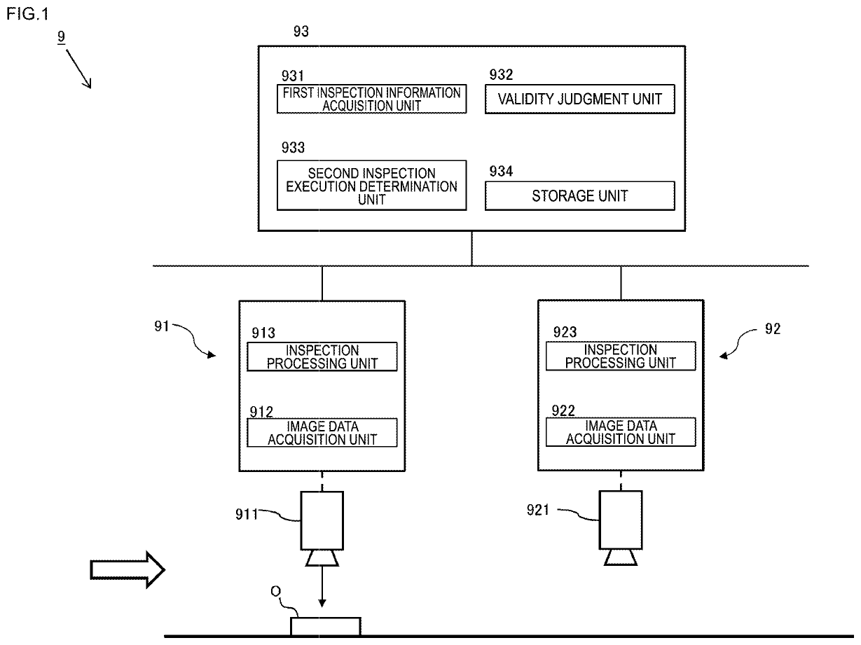

The present invention can be applied as, for example, an inspection management apparatus in a substrate inspection system including a plurality of inspection apparatuses each provided with different imaging systems. FIG. 1 is a schematic view illustrating a schematic configuration of the substrate inspection system to which the present invention is applied. As illustrated in FIG. 1, a substrate inspection system 9 according to the present application example includes a plurality of inspection apparatuses 91, 92 arranged on a production line (not illustrated) of a component-mounted substrate, an inspection management apparatus 93 that manages content and results of inspections, and a communication line such as a local area network (LAN) that connects these components to one another.

The inspection apparatuses 91, 92 each inspect a component-mounted substrate O, which is an inspection target, on the basis of image data obtained by an imaging unit imaging the component-mounted substrate, which is transported from the production line by a transport roller (not illustrated). As illustrated in FIG. 1, the inspection apparatuses 91, 92 include imaging units 911, 921, image data acquisition units 912, 922, and inspection processing units 913, 923, respectively. Note that the white arrow in FIG. 1 indicates a direction in which the component-mounted substrate O is transported.

In this example, different types of imaging units are employed as the imaging unit 911 of the inspection apparatus 91 and the imaging unit 921 of the inspection apparatus 92. For example, the imaging unit 911 may be a visible light camera and the imaging unit 921 may be an X-ray camera. Furthermore, in each inspection apparatus, the component-mounted substrate O is inspected by the inspection processing unit using a predetermined inspection program to judge whether the image data obtained by the imaging units and the image data acquisition units passes or fails.

The inspection management apparatus 93 can be constituted by, for example, a general-purpose computer and includes functional units of a first inspection information acquisition unit 931, a validity judgment unit 932, a second inspection execution determination unit 933, and a storage unit 934. In addition, although not illustrated, various input units such as a mouse and a keyboard, and output units such as a display are provided.

The first inspection information acquisition unit 931 acquires various kinds of information such as image data of the component-mounted substrate O, a measurement value of the component-mounted substrate O acquired on the basis of the image data, and a result of an inspection (pass/fail judgment) from the inspection apparatus 91.

In addition, the validity judgment unit 932 judges the validity of performing a second inspection on the component-mounted substrate O by the inspection apparatus 92 on the basis of the information acquired by the first inspection information acquisition unit 931 and a predetermined judgment condition.

In addition, the second inspection execution determination unit 933 determines whether to perform the inspection on the target component-mounted substrate O by the inspection apparatus 92 on the basis of the judgment by the validity judgment unit 932. In a case in which the inspection is to be performed, the second inspection execution determination unit 933 determines conditions (inspection item, resolution of acquired image, imaging range, etc.) under which the imaging and inspection are to be performed.

The storage unit 934 is constituted by a storage unit such as a random access memory (RAM) and a hard disk drive (HDD), and stores various kinds of information such as various kinds of design information related to the component-mounted substrate O (mounted components, placement relationships between components, etc.), component-related information (component type, component number, lot number, component image, etc.), an inspection program (inspection items, inspection criteria, etc.), past inspection image data, and past inspection result information.

(Validity Judgment Processing)

Next, validity judgment processing performed by the validity judgment unit 932 in the present application example will be described. The validity judgment unit 932 judges the validity of performing inspection on the target component-mounted substrate O (and components mounted thereon) by the inspection apparatus 92 on the basis of the predetermined judgment condition set in advance and information such as various kinds of design information related to the component-mounted substrate O stored in the storage unit 934, features of the image data acquired by the inspection apparatus 91, and the measurement value related to the shape of the inspection target component of the component-mounted substrate O. Note that one criterion for determining whether the secondary inspection by the inspection apparatus 92 is regarded as valid may be whether the result of the inspection (pass/fail judgment) by the inspection apparatus 91 can be regarded as an inspection result in a so-called gray zone having questionable reliability. Here, whether the result can be regarded as a result in the gray zone can be judged on the basis of whether the following condition is satisfied. Examples of the condition include the measurement value related to the shape of the inspection target component being a value in the vicinity of a threshold value of an inspection criterion, and the presence of noise in the acquired image data. However, even in a case in which the result is in the gray zone but performing the secondary inspection by the inspection apparatus 92 cannot ensure inspection accuracy (e.g., in a case in which the result is in the gray zone because a character on a component in the image acquired by the inspection apparatus 91 is unclear, and the inspection apparatus 92 is an X-ray inspection apparatus), the validity is non-existent (or low).

In a case in which the validity judgment unit 932 judges that there is no validity, the component-mounted substrate O to be subject to inspection is transported to a post-process without being inspected by the inspection apparatus 92. Alternatively, depending on the judgment of validity, reinspection may be performed by the inspection apparatus 91 after changing the inspection conditions.

On the other hand, in a case in which the validity judgment unit 932 judges that there is validity, the inspection conditions of the inspection apparatus 92 are determined and transmitted to the inspection apparatus 92. Then, the secondary inspection of the component-mounted substrate O is performed by the inspection apparatus 92 executing the inspection program reflecting the inspection conditions.

With the inspection management system 9 as described above, it is possible to determine whether to perform the secondary inspection on the inspection target subjected to the first inspection by an imaging system different from that of the first inspection after judging the validity of performing the secondary inspection. With this configuration, a needless secondary inspection of an inspection target for which the validity of performing the secondary inspection is low is not performed, and the secondary inspection is only performed when a secondary inspection is valid, thereby improving efficiency while maintaining inspection accuracy.

### EMBODIMENTS

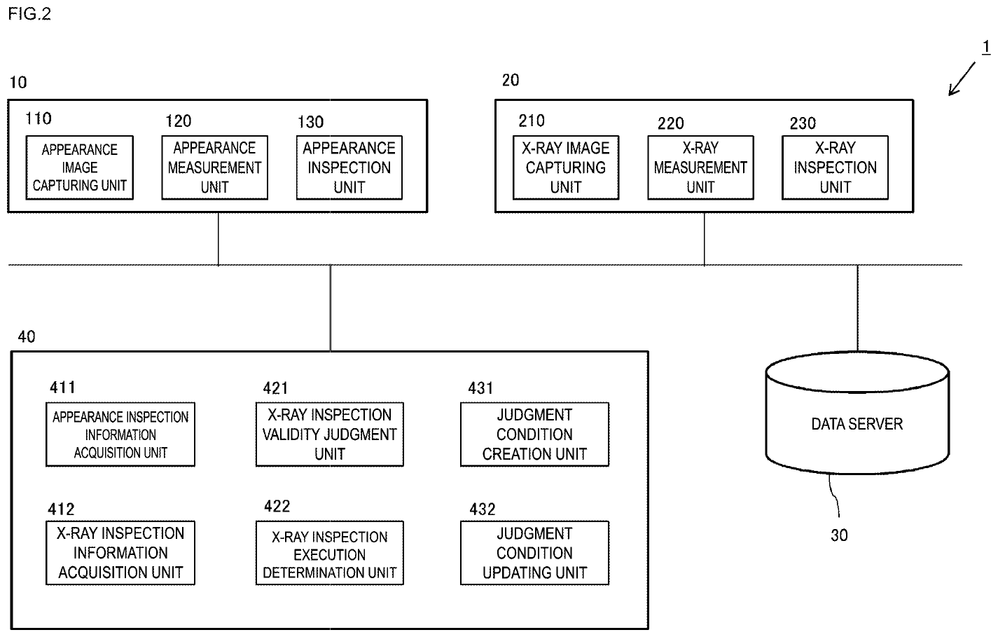

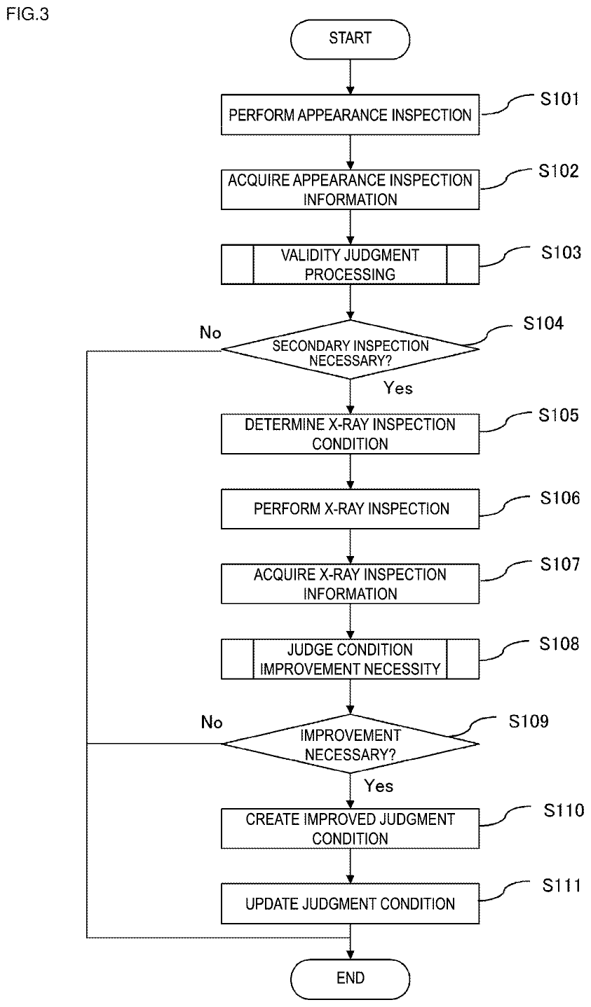

Hereinafter, an embodiment according to the present invention will be described in more detail with reference to FIGS. 2 and 3, taking as an example a system for inspecting a substrate by an appearance inspection apparatus and an X-ray inspection apparatus.

(System Configuration)

FIG. 2 is a block diagram illustrating an overview of a configuration of a substrate inspection system 1 according to the present embodiment. The substrate inspection system 1 according to the present embodiment generally includes an appearance inspection apparatus 10, an X-ray inspection apparatus 20, a data server 30, and an inspection management apparatus 40. These components are communicably connected to one another by a communication unit (not illustrated). The substrate inspection system 1 is a system configured to inspect a substrate on the basis of a measurement result of the substrate obtained by the appearance inspection apparatus 10 and a measurement result of the substrate obtained by the X-ray inspection apparatus 20.

The appearance inspection apparatus 10 is, for example, a apparatus that performs an appearance inspection on a component-mounted substrate using an inspection method that is a combination of a so-called phase shift method and a color highlight method. The inspection method that is a combination of the phase shift method and the color highlight method is a known technique and therefore a detailed description will not be provided. Performing such an inspection makes it possible, in a land portion of the substrate, to accurately detect the shape of an electrode recognizable from the appearance and a degree of inclination of a fillet. Note that the phase shift method is one technique for reconstructing a three-dimensional shape of an object surface by analyzing distortion of the pattern when pattern light is projected onto the object surface. Furthermore, the color highlight method is a method of representing a three-dimensional shape of a solder surface as two-dimensional hue information by irradiating the substrate with light of a plurality of colors (wavelengths) at different angles of incidence and capturing an image of the substrate in a state in which color features (colors of light sources in a specular reflection direction when viewed from a camera) corresponding to a normal direction of the solder surface appear on the solder surface.

The appearance inspection apparatus 10 generally includes functional units such as an appearance image capturing unit 110, an appearance measurement unit 120, and an appearance inspection unit 130 as well as a projector, a light source, and a stage for holding a substrate (none of which are illustrated). The appearance image capturing unit 110 captures an image of the substrate irradiated with light from the projector and the light source (not illustrated) and outputs an appearance inspection image. The appearance measurement unit 120 measures an appearance shape of (a mounted component on) the substrate on the basis of the appearance inspection image. The appearance inspection unit 130 inspects the appearance of the (mounted component on the) substrate, that is, judges whether the (mounted component on the) substrate passes or fails by comparing the measured appearance shape and the inspection criterion. Note that, in the following description, the phrase “inspection of substrate” also includes the inspection of components mounted on the substrate.

Note that information on the appearance inspection image, the measurement value of the appearance shape, and the appearance inspection result described above is respectively transmitted from the appearance inspection apparatus 10 to the data server 30 and stored in the data server 30.

The X-ray inspection apparatus 20 is, for example, an apparatus that measures the three-dimensional shape of the substrate by a method such as computed tomography (CT) or tomosynthesis, and that judges whether the substrate passes or fails on the basis of the three-dimensional shape.

The X-ray inspection apparatus 20 generally includes functional units such as an X-ray image capturing unit 210, an X-ray measurement unit 220, and an X-ray inspection unit 230 as well as an X-ray source and a stage for holding the substrate (neither of which are illustrated). The X-ray image capturing unit 210 captures an image of X-rays emitted from an X-ray source (not illustrated) and transmitted through the substrate, and outputs a tomographic image (hereinafter referred to as an X-ray image) of the substrate. The X-ray measurement unit 220 measures the three-dimensional shape of the substrate on the basis of a plurality of the X-ray images. The X-ray inspection unit 230 inspects the three-dimensional shape of the substrate, that is, judges whether the substrate passes or fails by comparing the measured three-dimensional shape and the inspection criterion.

Note that the X-ray image, the three-dimensional shape data, and the X-ray inspection result described above are transmitted from the X-ray inspection apparatus 20 to the data server 30 and stored in the data server 30.

The inspection management apparatus 40 may be, for example, a general-purpose computer. That is, although not illustrated, the inspection management apparatus 40 includes a processor such as a central processing unit (CPU) or a digital signal processor (DSP), a storage unit including a main storage unit such as a read-only memory (ROM) or a random access memory (RAM) and an auxiliary storage unit such as an erasable programmable read-only memory (EPROM), a hard disk drive (HDD), or a removable medium, an input unit such as a keyboard or a mouse, and an output unit such as a liquid crystal display. Note that the inspection management apparatus 40 may be constituted by a single computer or may be constituted by a plurality of computers that work in conjunction with one another.

The auxiliary storage unit stores an operating system (OS), various programs, various kinds of information related to the inspection target, various inspection criteria, and the like, the programs stored therein are loaded into a work area of the main storage unit and executed, and the components and the like are controlled through execution of the programs, whereby functional units that achieve predetermined purposes such as those described below can be realized. Note that some or all of the functional units may be realized by a hardware circuit such as an application-specific integrated circuit (ASIC) or a field-programmable gate array (FPGA).

Next, each functional unit included in the inspection management apparatus 40 will be described. The inspection management apparatus 40 includes the functional units of an appearance inspection information acquisition unit 411, an X-ray inspection information acquisition unit 412, an X-ray inspection validity judgment unit 421, an X-ray inspection execution determination unit 422, a judgment condition creation unit 431, and a judgment condition updating unit 432.

The appearance inspection information acquisition unit 411 acquires, from the data server 30 (or the appearance inspection apparatus 10), various kinds of information such as image data of the inspected substrate, the measurement value of the substrate acquired on the basis of the image data, and the result of inspection (pass/fail judgment). Similarly, the X-ray inspection information acquisition unit 412 acquires, from the data server 30 (or the X-ray inspection apparatus 20), various kinds of information such as image data of the inspected substrate, the measurement value of the substrate acquired on the basis of the image data, and the result of inspection (pass/fail judgment).

As will be described below, the X-ray inspection validity judgment unit 421 judges, on the basis of the information acquired by the appearance inspection information acquisition unit 411 and the predetermined judgment condition, whether further performing the X-ray inspection by the X-ray inspection apparatus 20 on the substrate subjected to the appearance inspection is valid. In addition, the X-ray inspection execution determination unit 422 determines, on the basis of the judgment by the X-ray inspection validity judgment unit 421 and the result of the appearance inspection, whether to perform the X-ray inspection on the substrate subject to inspection. In a case in which the X-ray inspection is to be performed, the X-ray inspection execution determination unit 422 determines the inspection conditions under which the X-ray inspection is to be performed.

The judgment condition creation unit 431 uses the information acquired by the X-ray inspection information acquisition unit 412 to create an improved judgment condition more appropriate for the validity judgment condition when a predetermined condition is satisfied. Note that the term “create” as used herein includes not only creation from scratch but also creation by changing an existing condition. Furthermore, the predetermined condition may be set to, for example, a case in which a ratio of substrates judged to be non-defective to the total number of substrates subjected to the X-ray inspection as the secondary inspection (hereinafter, also referred to as a non-defective rate) exceeds a predetermined value. In such a case, presumably the validity judgment criterion is loosely set. Thus, the judgment condition is preferably changed such that the validity judgment criterion of the X-ray inspection is stricter.

Furthermore, when the judgment condition creation unit 431 creates an improved judgment condition, the judgment condition updating unit 432 sets the improved judgment condition as the new validity judgment condition. Note that the judgment condition may be updated automatically, or may be updated upon reception of an instruction from an operator following a process of confirming with the operator whether it is acceptable to set the improved judgment condition.

(Processing Flow of Inspection System)

Next, a flow of inspection processing in the inspection management system 1 according to the present embodiment will be described with reference to FIG. 3. FIG. 3 is a flowchart illustrating the flow of processing. As illustrated in FIG. 3, first, an appearance inspection by the appearance inspection apparatus 10 is performed on (each component mounted on) a substrate subject to inspection (S101). Subsequently, the inspection management apparatus 40 acquires information including an appearance inspection result via the appearance inspection information acquisition unit 411 (S102).

Subsequently, the X-ray inspection validity judgment unit 421 judges whether performing the X-ray inspection on the substrate subject to inspection is valid (S103). The validity is judged according to the following conditions, for example.
(1) The measurement value of the inspection target component in the appearance inspection is in the vicinity of a threshold value of an inspection criterion.
(2-1) The design information of the substrate indicates a possibility of the inspection target component having a blind spot (another tall component is present close by).
(2-2) The design information of the substrate indicates a possibility of secondary reflection on the solder surface of the inspection target component (close to the solder surface of another component).
(3-1) In the appearance inspection image, the maximum luminance is saturated or the value of the minimum luminance is 0.
(3-2) The appearance inspection image has a low degree of similarity to a typical non-defective product image.

The validity may be judged according to any one of the conditions described above or a combination of the conditions described above. Note that the design information of the substrate includes information such as shapes and sizes of components mounted on the substrate subject to inspection (and lands) and placement relationships between the components. Such information may be stored in the data server 30.

Whether the above condition (3-1) or (3-2) is satisfied may be determined on the basis of the luminance or amount of noise in the image processing performed on the appearance inspection image, or may be determined using a trained model trained using past inspection performance results.

Returning to the description of the processing flow, when the processing of step S103 ends, the X-ray inspection execution determination unit 422 judges whether the X-ray inspection as the secondary inspection is necessary on the basis of the judgment by the X-ray inspection validity judgment unit 421 and the result information of the appearance inspection (S104). In a case in which it is determined that the X-ray inspection is not necessary, the processing is temporarily terminated, and the substrate is not subjected to the X-ray inspection and is transported to a post-process.

On the other hand, in a case in which it is determined in step S104 that the X-ray inspection is to be performed, the processing proceeds to step S105 and the inspection condition of the secondary inspection is determined by the X-ray inspection execution determination unit 422 (S105). Specifically, when the secondary inspection is judged to be valid due to, for example, insufficiency of a front fillet of the component to be inspected, the imaging condition is set (the resolution of the acquired image is increased) such that an image of a back fillet of the component can be captured at high resolution for accurate inspection in the X-ray inspection. Furthermore, the imaging range may be adjusted in accordance with the quantity and arrangement of components subject to the secondary inspection such that the time required for the X-ray inspection can be reduced to the extent possible.

When the inspection conditions of the X-ray inspection are determined in step S105, the conditions are transmitted to the X-ray inspection apparatus 20, and the X-ray inspection is performed by using an inspection program reflecting the conditions (S106). When the inspection is completed, the inspection management apparatus 40 acquires the X-ray inspection information including the result information of the X-ray inspection via the X-ray inspection information acquisition unit 412 (S107), and then performs a process of judging, on the basis of the X-ray inspection information, whether improvement of the judgment condition for the validity of performing the X-ray inspection is necessary (S108, S109). The method of judgment has been described above, and thus a detailed description thereof is omitted here.

In a case in which it is determined in step S109 that improvement of the validity judgment condition of the X-ray inspection is not necessary, the flow temporarily ends. On the other hand, in a case in which it is determined that improvement is necessary, an improved judgment condition is created by the judgment condition creation unit 431 (S110). The judgment condition may be improved in accordance with the reason why performing the X-ray inspection was deemed necessary. For example, in a case in which, in the processing of step S103 described above, satisfying condition (1) was a factor in judging that the X-ray inspection is valid, the range of the “vicinity” of the threshold value of the inspection criterion need only be narrowed. Furthermore, in a case in which satisfying conditions (2-1) and (2-2) described above was a factor in judging that the X-ray inspection is valid, the distance deemed “close” between the components on the substrate need only be shortened. Furthermore, in a case in which satisfying condition (3-2) described above was a factor in judging that the X-ray inspection is valid, the criterion for the degree of similarity to the non-defective product image need only be relaxed.

Subsequently, the judgment condition updating unit 432 applies the improved judgment condition created in step S110 (that is, updates the judgment condition of the validity of the X-ray inspection) (S111) and the series of processing ends.

With the inspection management system of the present embodiment as described above, in the inspection system for the component-mounted substrate including the appearance inspection apparatus and the X-ray inspection apparatus, it is possible to perform the X-ray inspection only on substrates for which the validity of performing the X-ray inspection as the secondary inspection was confirmed among the substrates for which an inspection result in the gray zone was obtained in the appearance inspection. This makes it possible to construct an inspection system that maintains a certain level of accuracy without reducing the efficiency of the entire inspection caused by performing needless reinspection.

<Others>

The examples described above are merely illustrative of the present invention, and the present invention is not limited to the specific aspects described above. The present invention can be modified and combined in various ways within the scope of the technical idea of the present invention. For example, although the present invention is described as a system including an inspection apparatus in each of the examples described above, the present invention can also be regarded as an inspection management apparatus. Furthermore, although the first inspection and the second inspection are performed by the respective inspection apparatuses in the examples described above, the present invention can be applied to a single inspection apparatus including a plurality of different imaging systems and having a plurality of inspection functions corresponding to the imaging systems.

Furthermore, although the validity of performing the secondary inspection is judged for substrates having a result in the gray zone in the primary inspection in each of the examples described above, the validity may be judged under the condition that the substrate is judged to be a non-defective product in the primary inspection. When the secondary inspection is performed on a product despite the product being judged to be defective in the primary inspection and the product being judged to be non-defective in the secondary inspection, a so-called missed defect is more likely to occur. From this point of view, it is desirable to consistently treat defective results in the primary inspection as a defect.

Furthermore, although the embodiment described above has a configuration in which the inspection management apparatus 40 for creating the inspection program is provided separately from the appearance inspection apparatus 10 and the X-ray inspection apparatus 20, each functional unit of the inspection management apparatus 40 may be provided in either the appearance inspection apparatus 10 or the X-ray inspection apparatus 20 to perform the processing of each step described above without providing the inspection management apparatus 40 separately.

Furthermore, in the embodiments described above, although the appearance inspection apparatus 10 is described as using an inspection method that is a combination of the phase shift method and the color highlight method, the apparatus may be an appearance inspection apparatus that performs inspection using only the phase shift method or only the color highlight method.

Furthermore, the present invention is not limited to the combination of the appearance inspection apparatus and the X-ray inspection apparatus, and is also applicable to a combination of a laser scanning measurement apparatus and the X-ray inspection apparatus.

<Supplementary Note 1>

An inspection system including:
a first inspection unit (10) configured to perform a first inspection on the basis of first image data obtained by imaging an inspection target by a first imaging unit (110); a second inspection unit (20) configured to perform a second inspection on the basis of second image data obtained by imaging the inspection target by a second imaging unit (210) different from the first imaging unit;
a first inspection information acquisition unit (411) configured to acquire first inspection information including a result of the first inspection from the first inspection unit;
a validity judgment unit (421) configured to judge, on the basis of a predetermined judgment condition, a validity of performing the second inspection on the inspection target by the second inspection unit; and
a second inspection execution determination unit (422) configured to determine, on the basis of the judgment by the validity judgment unit, at least a necessity of performing the second inspection.

<Supplementary Note 2>

An inspection management apparatus that is a management apparatus (93) of an inspection system (9) including a first inspection unit (91) configured to perform a first inspection on the basis of first image data obtained by imaging an inspection target (O) by a first imaging unit (911), and a second inspection unit (92) configured to perform a second inspection on the basis of second image data obtained by imaging the inspection target by a second imaging unit (921) different from the first imaging unit, the inspection management apparatus including:
a first inspection information acquisition unit (931) configured to acquire first inspection information including a result of the first inspection from the first inspection unit;
a validity judgment unit (932) configured to judge, on the basis of a predetermined judgment condition, a validity of performing the second inspection on the inspection target by the second inspection unit; and
a second inspection execution determination unit (933) configured to determine, on the basis of the judgment by the validity judgment unit, at least a necessity of performing the second inspection.

<Supplementary Note 3>

An inspection method including:
a first inspection step (S101) of performing a first inspection on the basis of first image data obtained by imaging an inspection target by a first imaging unit;
a first inspection information acquisition step (S102) of acquiring first inspection information including a result of the first inspection;
a validity judgment step (S103) of judging, on the basis of a predetermined judgment condition, a validity of performing a second inspection on the inspection target on the basis of second image data obtained by imaging the inspection target by a second imaging unit different from the first imaging unit; and a second inspection execution determination step (S105) of determining, on the basis of the judgment by the validity judgment step, at least a necessity of performing the second inspection and content of the second inspection.

### DESCRIPTION OF SYMBOLS

1,9 substrate inspection system
appearance inspection apparatus
110 appearance image capturing unit
120 appearance measurement unit
130 appearance inspection unit
X-ray inspection apparatus
210 X-ray image capturing unit
220 X-ray measurement unit
230 X-ray inspection unit
30 data server
40,93 inspection management apparatus
91,92 inspection apparatus
911,921 imaging unit
O component-mounted substrate

1. An inspection system comprising:
a first inspection unit configured to perform a first inspection on the basis of first image data obtained by imaging an inspection target by a first imaging unit;
a second inspection unit configured to perform a second inspection on the basis of second image data obtained by imaging the inspection target by a second imaging unit different from the first imaging unit;
a first inspection information acquisition unit configured to acquire first inspection information including a result of the first inspection from the first inspection unit;
a validity judgment unit configured to judge, on the basis of a predetermined judgment condition, a validity of performing the second inspection on the inspection target by the second inspection unit; and
a second inspection execution determination unit configured to determine, on the basis of the judgment by the validity judgment unit, at least a necessity of performing the second inspection.

2. The inspection system according to claim 1,
wherein in a case in which the second inspection execution determination unit determines to perform the second inspection, the second inspection execution determination unit also determines content of the second inspection.

3. The inspection system according to claim 1,
wherein the second inspection execution determination unit determines that the second inspection is to be performed in a case in which the result of the first inspection is no abnormality and the validity judgment unit judges that performing the second inspection is valid.

4. The inspection system according to claim 1, further comprising:
a second inspection information acquisition unit configured to acquire second inspection information including a result of the second inspection from the second inspection unit; and
a judgment condition creation unit configured to create an improved judgment condition more appropriate for the judgment condition by using at least the second inspection information.

5. The inspection system according to claim 4,
wherein the second inspection information includes a second inspection non-defective rate indicating a ratio of a quantity of a plurality of the inspection targets judged to be non-defective to a total quantity of the plurality of inspection targets subjected to the second inspection, and
the judgment condition creation unit performs a process of creating the improved judgment condition in a case in which the second inspection non-defective rate exceeds a predetermined threshold value.

6. The inspection system according to claim 4, further comprising
a judgment condition updating unit configured to newly set the improved judgment condition created by the judgment condition creation unit as the predetermined judgment condition.

7. The inspection system according to claim 1,
wherein the validity judgment unit judges the validity on the basis of the predetermined judgment condition set for at least one of the first image data, a measurement value related to a shape of the inspection target obtained on the basis of the first image data, or information related to design of the inspection target.

8. The inspection system according to claim 1,
wherein the validity judgment unit includes a trained model obtained by performing machine learning using a training data set including, of the first image data related to the first inspection performed on the inspection target in the past, the first image data of the inspection target resulting in a false negative and/or a false positive in the first inspection.

9. The inspection system according to claim 1,
wherein the inspection target is a component-mounted substrate.

10. The inspection system according to claim 1,
wherein the first imaging unit is a visible light camera and the second imaging unit is an X-ray camera.

11. An inspection management apparatus that is a management apparatus of an inspection system including a first inspection unit configured to perform a first inspection on the basis of first image data obtained by imaging an inspection target by a first imaging unit, and a second inspection unit configured to perform a second inspection on the basis of second image data obtained by imaging the inspection target by a second imaging unit different from the first imaging unit, the inspection management apparatus comprising:
a first inspection information acquisition unit configured to acquire first inspection information including a result of the first inspection from the first inspection unit;
a validity judgment unit configured to judge, on the basis of a predetermined judgment condition, a validity of performing the second inspection on the inspection target by the second inspection unit; and
a second inspection execution determination unit configured to determine, on the basis of the judgment by the validity judgment unit, at least a necessity of performing the second inspection.

12. An inspection method comprising:
a first inspection step of performing a first inspection on the basis of first image data obtained by imaging an inspection target by a first imaging unit;
a first inspection information acquisition step of acquiring first inspection information including a result of the first inspection;
a validity judgment step of judging, on the basis of a predetermined judgment condition, a validity of performing a second inspection on the inspection target on the basis of second image data obtained by imaging the inspection target by a second imaging unit different from the first imaging unit; and
a second inspection execution determination step of determining, on the basis of the judgment in the validity judgment step, at least a necessity of performing the second inspection.

13. The inspection method according to claim 12, further comprising:
a second inspection step of performing the second inspection,
wherein the second inspection execution determination step further includes, in a case in which performing the second inspection is determined, also determining content of the second inspection, and
the second inspection is performed, in a case in which the content of the second inspection is determined in the second inspection execution determination step, using the content of the second inspection determined.

14. The inspection method according to claim 12, further comprising:
a second inspection information acquisition step of acquiring second inspection information including a result of the second inspection; and
an improved judgment condition creation step of creating an improved judgment condition more appropriate for the judgment condition by using at least the second inspection information.

15. The inspection method according to claim 14, further comprising a judgment condition updating step of newly setting the judgment condition created in the improved judgment condition creation step as the predetermined judgment condition.

16. A non-transitory computer readable medium storing a program for causing a computer to execute each step of the inspection method according to claim 12.
